(19) United States
(12) Patent Application Publication
(10) Pub. No.: US 2007/0064514 A1
(43) Pub. Date: Mar. 22, 2007

(54) Control unit and portable terminal

(75) Inventors: Hideaki Miyamoto, Ogaki-shi (JP); Shigeharu Matsushita, Osaka (JP); Shinichiro Okada, Toyohashi-shi (JP)

Correspondence Address: MCDERMOTT WILL & EMERY LLP, 600 13TH STREET, N.W., WASHINGTON, DC, 20005-3096, US

(73) Assignee: SANYO ELECTRIC CO., LTD.

(21) Appl. No.: 11/525,010

(22) Filed: Sep. 22, 2006

(30) Foreign Application Priority Data
Sep. 22, 2005 (JP) JP2005-275239
Nov. 29, 2005 (JP) JP2005-344047

(51) Int. Cl. G11C 5/14

(52) U.S. Cl. 365/228

(57) ABSTRACT

A control unit capable of reliably preventing loss of data also when losing power during data processing is obtained. This control unit comprises a volatile memory temporarily storing data used in the control unit and a nonvolatile memory holding data of the volatile memory, for writing the same data as that written in the volatile memory also in the nonvolatile memory upon occurrence of writing in the volatile memory.

### BACKGROUND OF THE INVENTION

1. Field of the Invention

The present invention relates to a control unit and a portable terminal, and more particularly, it relates to a control unit and a portable terminal each having a function of backing up data before losing power.

2. Description of the Background Art

A control unit performing data processing must back up data processed in a working memory for preventing loss of data when power is lost during data processing. The working memory employed in the control unit is formed by a volatile memory such as an SRAM (static random access memory) or a DRAM (dynamic random access memory) in view of an operating speed and a rewritable frequency. When losing power, however, the volatile memory loses data held therein.

On the other hand, Japanese Patent Laying-Open No. 2001-34535 discloses a method of writing data from a cache memory constituted of a volatile memory in a flash memory constituted of a nonvolatile memory thereby holding the data when a voltage detecting circuit detects reduction of a power supply voltage and rewriting the data held in the flash memory in a hard disk upon subsequent power supply for recovering the data to the state held before loss of power. In other words, the flash memory backs up the data before the power is lost.

In general, however, a time of at least several μsec. is necessary for writing data in the flash memory. According to the method disclosed in Japanese Patent Laying-Open No. 2001-34535, therefore, data cannot be correctly written in the flash memory since the power is lost before the data is entirely written in the flash memory from the cache memory.

### SUMMARY OF THE INVENTION

The present invention has been proposed in order to solve the aforementioned problem, and an object of the present invention is to provide a control unit capable of reliably preventing loss of data also when losing power during data processing.

In order to attain the aforementioned object, a control unit according to a first aspect of the present invention comprises a control portion partially or entirely controlling the control unit, a volatile memory temporarily storing data used in the control unit and a nonvolatile memory holding data of the volatile memory, for writing the same data as that written in the volatile memory also in the nonvolatile memory upon occurrence of writing in the volatile memory.

The control unit according to the first aspect, exercising control for writing the same data as that written in the volatile memory also in the nonvolatile memory every data writing in the volatile memory as hereinabove described, can avoid such a problem arising in the prior art that power is lost before the control unit completely writes data in the nonvolatile memory when writing the data from the volatile memory in the nonvolatile memory upon reduction of the power supply voltage. Thus, the control unit can reliably prevent loss of data also when losing power during data processing.

The aforementioned control unit according to the first aspect preferably further comprises an address detecting portion detecting whether or not data is written in a prescribed address space of the volatile memory, for writing the same data as that written in the volatile memory also in the nonvolatile memory when the address detecting portion detects that data is written in the prescribed address space of the volatile memory. According to this structure, the control unit can preserve the same data as that written in the address space of the volatile memory storing data necessary for data processing in the nonvolatile memory when detecting this data writing, thereby storing only data necessary for data processing after power supply in the nonvolatile memory. Thus, the cost for the control unit and power consumption therein can be suppressed.

In this case, the address detecting portion preferably detects whether or not data is written in an address space for temporarily storing data used in the control portion. According to this structure, the control unit can restore data used in the control portion upon subsequent power supply after losing power, thereby continuing data processing performed before the power has been lost.

In the aforementioned control unit according to the first aspect, a speed for writing data in the nonvolatile memory is preferably equivalent to or in excess of a speed for writing data in the volatile memory. In this case, “equivalent to” corresponds to “substantially identical to”, and the speed for writing data in the nonvolatile memory may be at least about 1/10 of the speed for writing data in the volatile memory. According to this structure, the control unit can immediately complete data writing in the nonvolatile memory, thereby avoiding such a problem that power is lost in an intermediate stage of the operation of writing data written in the volatile memory also in the nonvolatile memory.

In this case, the nonvolatile memory preferably includes either a ferroelectric memory or a magnetoresistive memory. According to this structure, such a problem that power is lost in an intermediate stage of the operation of writing data written in the volatile memory also in the nonvolatile memory can be easily avoided since data can be written in the ferroelectric memory or the magnetoresistive memory at a speed equivalent to or in excess of the speed for writing data in the volatile memory.

The aforementioned control unit according to the first aspect preferably rewrites data held in the nonvolatile memory in the volatile memory when power starts to be supplied to the control unit. According to this structure, the control unit can rewrite data held in the nonvolatile memory in the volatile memory when supplied with power again also when the control unit loses power to result in loss of data stored in the volatile memory, thereby restoring at least partial data of the volatile memory to the state held before the power has been lost. Thus, the control unit can continue the data processing, performed before the power has been lost, after the same is supplied with power again.

A portable terminal according to a second aspect of the present invention comprises an antenna receiving a radio signal, a conversion portion frequency-converting the received radio signal to a baseband signal, a processing portion demodulating the baseband signal, a control portion partially or entirely controlling the portable terminal on the basis of the demodulated baseband signal, a volatile memory temporarily storing data used in the portable terminal and a nonvolatile memory holding data of the volatile memory, for writing the same data as that written in the volatile memory also in the nonvolatile memory upon occurrence of writing in the volatile memory.

A portable terminal, generally driven by a battery, frequently loses power during processing due to power consumption in the battery. However, the portable terminal according to the second aspect, writing the same data as that written in the volatile memory also in the nonvolatile memory as hereinabove described, can reliably prevent loss of data also when losing power during processing. Thus, the portable terminal can continue the processing, performed before the power has been lost, when supplied with power again.

The aforementioned portable terminal according to the second aspect preferably further comprises an address detecting portion detecting whether or not data is written in a prescribed address space of the volatile memory, for writing the same data as that written in the volatile memory also in the nonvolatile memory when the address detecting portion detects that data is written in the prescribed address space of the volatile memory. According to this structure, the portable terminal can preserve the same data as that written in the address space of the volatile memory storing data necessary for data processing in the nonvolatile memory when detecting this data writing, thereby storing only data necessary for data processing upon power supply in the nonvolatile memory. Thus, the cost for the portable terminal and power consumption therein can be suppressed.

In this case, the address detecting portion preferably detects whether or not data is written in an address space for temporarily storing data used in the control portion. According to this structure, the portable terminal can restore data used in the control portion upon subsequent power supply after losing power, thereby continuing data processing performed before the power has been lost.

In the aforementioned portable terminal according to the second aspect, a speed for writing data in the nonvolatile memory is preferably equivalent to or in excess of a speed for writing data in the volatile memory. In this case, “equivalent to” corresponds to “substantially identical to”, and the speed for writing data in the nonvolatile memory may be at least about 1/10 of the speed for writing data in the volatile memory. According to this structure, the portable terminal can immediately complete data writing in the nonvolatile memory, thereby avoiding such a problem that power is lost in an intermediate stage of the operation of writing data written in the volatile memory also in the nonvolatile memory.

In this case, the nonvolatile memory preferably includes either a ferroelectric memory or a magnetoresistive memory. According to this structure, such a problem that power is lost in an intermediate stage of the operation of writing data written in the volatile memory also in the nonvolatile memory can be easily avoided since data can be written in the ferroelectric memory or the magnetoresistive memory at a speed equivalent to or in excess of the speed for writing data in the volatile memory.

The aforementioned portable terminal according to the second aspect preferably rewrites data held in the nonvolatile memory in the volatile memory when power starts to be supplied to the portable terminal. According to this structure, the portable terminal can rewrite data held in the nonvolatile memory in the volatile memory when supplied with power again also when losing power to result in loss of data stored in the volatile memory, thereby restoring at least partial data of the volatile memory to the state held before the power has been lost. Thus, the portable terminal can continue data processing, performed before the power has been lost, when supplied with power again.

A control unit according to a third aspect of the present invention comprises a control portion partially or entirely controlling the control unit and a memory portion including a volatile memory and a nonvolatile memory temporarily storing data used in the control unit, and the memory portion stores partial data used in the control unit in the nonvolatile memory while storing remaining data in the volatile memory.

The control unit according to the third aspect, capable of directly storing data to be held before losing power in the nonvolatile memory as hereinabove described, can avoid such a problem arising in the prior art that power is lost before the control unit completely writes the data in the nonvolatile memory when writing the data from the volatile memory in the nonvolatile memory upon reduction of the power supply voltage. Thus, the control unit can reliably prevent loss of data also when losing power during data processing. Further, the nonvolatile memory requires a capacitance for only data to be held before losing power and is used as a working memory of the control unit as such, whereby the capacitance of the volatile memory can also be reduced. Consequently, the cost for the control unit and power consumption therein can be suppressed.

In the aforementioned control unit according to the third aspect, the memory portion preferably further includes an address detecting portion exercising control for writing data in the nonvolatile memory when detecting data writing in a prescribed address space among address spaces allocated to the memory portion. According to this structure, the control unit can simply detect whether or not data written in the memory portion is to be held before losing power from the address storing the data.

In the aforementioned control unit according to the third aspect, the partial data stored in the nonvolatile memory is preferably data used in the control portion. According to this structure, the control unit can restore data used in the control portion from the nonvolatile memory upon subsequent power supply after losing power, thereby continuing data processing performed before the power has been lost.

In the aforementioned control unit according to the third aspect, the nonvolatile memory preferably includes either a ferroelectric memory or a magnetoresistive memory. According to this structure, the nonvolatile memory can easily store partial data included in data used in the control unit, whereby the control unit can reliably prevent loss of data also when losing power during data processing.

A portable terminal according to a fourth aspect of the present invention comprises an antenna receiving a radio signal, a conversion portion frequency-converting the received radio signal to a baseband signal, a processing portion demodulating the baseband signal, a control portion partially or entirely controlling the portable terminal on the basis of the demodulated baseband signal and a memory portion including a volatile memory and a nonvolatile memory temporarily storing data used in the portable terminal, and the memory portion stores partial data used in the portable terminal in the nonvolatile memory while storing remaining data in the volatile memory.

A portable terminal, generally driven by a battery, frequently loses power during processing due to power consumption in the battery. However, the portable terminal according to the fourth aspect, storing partial data included in data used in the portable terminal in the nonvolatile memory as hereinabove described, can reliably prevent loss of data also when losing power during processing. Thus, the portable terminal can continue the processing, performed before the power has been lost, when supplied with power again.

In the aforementioned portable terminal according to the fourth aspect, the memory portion preferably further includes an address detecting portion exercising control for writing data in the nonvolatile memory when detecting data writing in a prescribed address space among address spaces allocated to the memory portion. According to this structure, the portable terminal can simply detect whether or not data written in the memory portion is to be held before losing power from the address storing the data.

In the aforementioned portable terminal according to the fourth aspect, the partial data stored in the nonvolatile memory is preferably data used in the control portion. According to this structure, the portable terminal can restore data used in the control portion from the nonvolatile memory upon subsequent power supply after losing power, thereby continuing data processing performed before the power has been lost.

In the aforementioned portable terminal according to the fourth aspect, the nonvolatile memory preferably includes either a ferroelectric memory or a magnetoresistive memory. According to this structure, the nonvolatile memory can easily store partial data included in data used in the portable terminal, whereby the portable terminal can reliably prevent loss of data also when losing power during data processing.

A control unit according to a fifth aspect of the present invention comprises a storage portion storing a first program for controlling a system and a second program for updating the first program, a control portion executing the first program and the second program, a volatile memory temporarily storing data used in the control portion and a nonvolatile memory holding data of the volatile memory, for temporarily storing the second program in the volatile memory and holding the second program in the nonvolatile memory when updating the first program.

When updating the program, the control unit stores the second program, which is an update program, in the volatile memory and thereafter temporarily erases the second program from the storage portion along with the first program. In this case, the control unit according to the fifth aspect also holds the second program in the nonvolatile memory as described above, whereby the control unit can store the second program held in the nonvolatile memory in the volatile memory again upon subsequent power supply although the second program stored in the volatile memory disappears if the control unit loses power during the operation of updating the first program. Thus, the control unit can reliably prevent the second program from disappearance when losing power, thereby executing the operation of updating the program again.

A control unit according to a sixth aspect of the present invention comprises a storage portion storing a first program for controlling the control unit and a second program for updating the first program, a control portion executing the first program and the second program and a memory portion including a volatile memory temporarily storing data used in the control unit and a nonvolatile memory, for holding the second program in the nonvolatile memory when updating the first program, and the control portion reads the second program held in the nonvolatile memory.

When updating the program, the control unit temporarily erases the second program, which is an update program, from the storage portion along with the first program. In this case, the control unit according to the sixth aspect also holds the second program in the nonvolatile memory as described above, whereby the control unit can reliably prevent the second program from disappearance when losing power, thereby executing the operation of updating the program again. Further, the control portion updates the program by reading the second program held in the nonvolatile memory without storing the second program in the volatile memory, whereby the capacitance of the volatile memory can also be reduced. Consequently, the cost for the control unit and power consumption therein can be suppressed.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a block diagram of a control unit according to a first embodiment of the present invention;

FIG. 2 is a block diagram of a portable terminal according to a second embodiment of the present invention;

FIG. 3 is a block diagram of a control unit according to a third embodiment of the present invention; and

FIG. 4 is a block diagram of a portable terminal according to a fourth embodiment of the present invention.

### DESCRIPTION OF THE PREFERRED EMBODIMENTS

Embodiments of the present invention are now described with reference to the drawings.

### First Embodiment

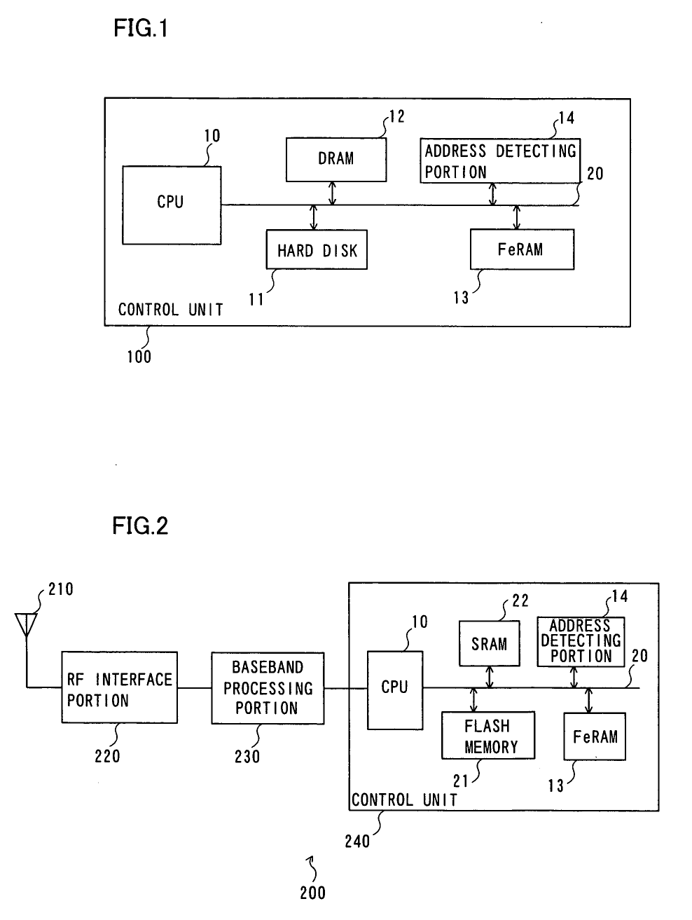

The structure of a control unit 100 according to a first embodiment of the present invention is described with reference to FIG. 1.

As shown in FIG. 1, the control unit 100 according to the first embodiment comprises a CPU (central processing unit) 10, a hard disk 11, a DRAM (dynamic random access memory) 12, an FeRAM (ferroelectric random access memory) 13 and an address detecting portion 14. The CPU 10 is an example of the “control portion” in the present invention. The DRAM 12 is an example of the “volatile memory” in the present invention, and the FeRAM 13 is an example of the “nonvolatile memory” in the present invention. The respective blocks are connected to a bus 20, for transmitting/receiving data to/from each other through the bus 20.

The CPU 10 has a function of executing the entire control and operation of the control unit 100 according to a program stored in the hard disk 11. The CPU 10 also has a function of monitoring a power supply voltage and detecting loss of power during data processing. When detecting loss of power during data processing, the CPU 10 posts this to the address detecting portion 14 described later in subsequent power supply.

The hard disk 11 has a function of storing the program for driving the CPU 10 and data used for the program. This hard disk 11 may be replaced with a flash memory.

The DRAM 12 is a volatile memory employed as a working memory temporarily holding data used in the control unit 100. A prescribed address space of the DRAM 12 is employed as a working memory of the CPU 10, so that data necessary for operation of the CPU 10 and results of the operation are written in the prescribed address space. The address space employed as the working memory of the CPU 10 may be regularly fixed, or may be rendered variable with the program.

The FeRAM 13 is a nonvolatile memory functioning as a backup memory for holding data stored in the prescribed address space employed as the working memory of the CPU 10 among data stored in the DRAM 12 along with the DRAM 12. When the control unit 100 loses power and the DRAM 12 loses data, the control unit 100 can continue data processing performed before the power has been lost if data used in the CPU 10 can be restored upon subsequent power supply. The FeRAM 13 is employed as the backup memory for such data restoration.

The DRAM 12 employed as the working memory of the control unit 100 in FIG. 1 may simply be a volatile memory such as an SRAM (static random access memory), for example, in view of the operating speed and the rewritable frequency. Further, the FeRAM 13 employed as the backup memory for the volatile DRAM 12 in FIG. 1 may simply be a nonvolatile memory such as an MRAM (magnetoresistive random access memory), for example, allowing reading/writing at a speed equivalent to or in excess of that for a volatile memory.

The address detecting portion 14 monitors writing in the DRAM 12. When data is written in the prescribed address space employed as the working memory of the CPU 10, the address detecting portion 14 exercises control for writing the same data as that written in the address space also in the FeRAM 13.

More specifically, control, address and data signals for the DRAM 12 are connected to the address detecting portion 14, which in turn monitors presence/absence of data writing in the DRAM 12 from the control signal for the DRAM 12. When detecting writing in the DRAM 12 from the level of the address signal for the DRAM 12, the address detecting portion 14 detects whether or not the data is written in the prescribed address space employed as the working memory of the CPU 10. The CPU 10 transmits information of the address space employed as the working memory thereof to the address detecting portion 14.

When the data is written in the prescribed address space of the DRAM 12, the address detecting portion 14 generates control, address and data signals for the FeRAM 13 to write the same data as that written in the DRAM 12 also in the FeRAM 13 along with the value of the address of the DRAM 12 storing the data. According to the control signal etc. generated in the address detecting portion 14, the FeRAM 13 holds the same data as that written in the DRAM 12 and the address of the DRAM 12 storing the data.

When receiving information indicating that power has been lost during data processing from the CPU 10, the address detecting portion 14 exercises control for reading the data written in the DRAM 12 and the address of the DRAM 12 storing the data from the FeRAM 13 and restoring the data of the DRAM 12. In other words, the address detecting portion 14 writes the read data in the address space of the DRAM 12 corresponding to the data read from the FeRAM 13. Thus, the data having been stored before the power has been lost is restored in the address space of the DRAM 12 employed as the working memory of the CPU 10.

Operations of the control unit 100 shown in FIG. 1 are now described. The CPU 10 properly downloads the program stored in the hard disk 11, for executing overall control and operation of the control unit 100 according to this program. At this time, the CPU 10 reads data used therein from the hard disk 11 and writes the same in the prescribed address space of the DRAM 12 employed as the working memory thereof. The CPU 10 also writes and holds results of operation thereof in the prescribed address space of the DRAM 12. The DRAM 12 further temporarily stores various data used in the control unit 100.

When data is written in the DRAM 12, the address detecting portion 14 detects this writing in the DRAM 12 and determines whether or not the data is written in the prescribed address space employed as the working memory of the CPU 10. When determining that the data is written in the prescribed address space, the address detecting portion 14 writes the same data as that written in the address space also in the FeRAM 13 along with the value of the address storing the data.

When the control unit 100 loses power during data processing, the DRAM 12 entirely loses the data written therein while the FeRAM 13 holds the data written therein. Upon subsequent power supply, the CPU 10 detects that power has been lost during data processing and transmits this information to the address detecting portion 14. On the basis of this information signal transmitted thereto, the address detecting portion 14 exercises control for rewriting the data from the FeRAM 13 in the prescribed address space of the DRAM 12 having been employed as the working memory of the CPU 10. Thus, the control unit 100 can restore data necessary for driving the CPU 10 to the state held before power has been lost, among the data lost from the DRAM 12.

According to the first embodiment, as hereinabove described, the control unit 100 comprises the DRAM 12 temporarily storing data used in the control unit 100 and the FeRAM 13 holding the data of the DRAM 12 for writing the same data as that written in the DRAM 12 also in the FeRAM 13 every time data is written in the prescribed address space of the DRAM 12, thereby avoiding such a problem arising in the prior art that power is lost before the control unit 100 completely writes the data in the FeRAM 13 when writing the data from the DRAM 12 in the FeRAM 13 upon reduction of the power supply voltage. Thus, the control unit 100 can reliably prevent loss of data also when losing power during data processing.

According to the first embodiment, as hereinabove described, the control unit 100 further comprises the address detecting portion 14 detecting whether or not data is written in the prescribed address space of the DRAM 12 for writing the same data as that written in the DRAM 12 also in the FeRAM 13 when the address detecting portion 14 detects that the data is written in the prescribed address space of the DRAM 12 and preserving the same data in the FeRAM 13 when detecting that the data is written in the address space of the DRAM 12 for storing data necessary for data processing, thereby storing only data necessary for data processing upon power supply in the FeRAM 13. Thus, the cost for the control unit 100 and power consumption therein can be suppressed.

According to the first embodiment, as hereinabove described, the address detecting portion 14, so formed as to detect whether or not data is written in the address space for temporarily storing data used in the CPU 10, can restore the data having been used in the CPU 10 upon subsequent power supply after power has been lost, thereby continuously performing the data processing performed before the power has been lost.

According to the first embodiment, as hereinabove described, the control unit 100 can immediately complete data writing in the FeRAM 13 at a speed equivalent to or in excess of the speed for writing data in the DRAM 12, thereby avoiding such a problem that power is lost in an intermediate stage of the operation of writing data written in the DRAM 12 also in the FeRAM 13. Thus, the control unit 100 can reliably prevent loss of data also when losing power during data processing.

According to the first embodiment, as hereinabove described, the control unit 100 employing the FeRAM 13 exhibiting a writing speed equivalent to or in excess of that of the DRAM 12 as the nonvolatile memory can easily avoid such a problem that power is lost during an intermediate stage of the operation of writing the data written in the DRAM 12 also in the FeRAM 13.

According to the first embodiment, as hereinabove described, the control unit 100 rewriting the data held in the FeRAM 13 in the DRAM 12 upon power supply can rewrite data held in the FeRAM 13 in the DRAM 12 when supplied with power again also when the control unit 100 loses power and the DRAM 12 loses data stored therein, thereby restoring at least partial data of the DRAM 12 to the state held before power has been lost. Thus, the control unit 100 can continue data processing, performed before the power has been lost, when supplied with power again.

### Second Embodiment

The structure of a portable terminal 200 according to a second embodiment of the present invention is now described wit reference to FIG. 2. According to the second embodiment, a control unit 240 similar to the control unit 100 according to the first embodiment is applied to the portable terminal 200.

The portable terminal 200 according to the second embodiment comprises an antenna 210, an RF interface portion 220, a baseband processing portion 230 and the control unit 240, as shown in FIG. 2.

The antenna 210 receives a signal from a transmitter (not shown) through radio. The RF interface portion 220 frequency-converts the signal of a radio frequency received in the antenna 210 to a baseband signal. The baseband processing portion 230 demodulates the baseband signal.

The control unit 240 implements various applications by controlling the portable terminal 200 with the demodulated baseband signal and a built-in program (system program) in a structure similar to that of the control unit 100 according to the first embodiment. However, a flash memory 21 and an SRAM 22 substitute for the hard disk 11 and the DRAM 12 of the control unit 100 respectively. The remaining blocks of the control unit 240 are identical to those of the control unit 100 according to the first embodiment, and denoted by the same reference numerals.

The flash memory 21 of the control unit 240 stores the built-in program. The portable terminal 200 can update the built-in program, in order to solve inconveniences of the system or add functions thereto. Therefore, an update program for updating the system program is written in the flash memory 21, in addition to the ordinary built-in program (system program).

When the portable terminal 200 ordinarily operates, a CPU 10 controls the portable terminal 200 according to the system program. At this time, the control unit 240 of the portable terminal 200 backs up data used in the CPU 10 in an FeRAM 13 similarly to the control unit 100 according to the first embodiment. When data is written in a prescribed address space of the SRAM 22 employed as a working memory of the CPU 10, the control unit 240 writes the same data as that written in the address space also in the FeRAM 13. When the portable terminal 200 loses power during data processing, therefore, the control unit 240 can rewrite the contents of the FeRAM 13 in the prescribed address space of the SRAM 22 upon subsequent power supply.

In order to update the system program, the CPU 10 rewrites data of the system program according to the update program. The procedure for updating the system program is now described.

The transmitter (not shown) transmits a signal indicating presence of an updated system program, so that the portable terminal 200 receives this signal through the antenna 210 and transmits the same to the CPU 10 of the control unit 240 through the RF interface portion 220 and the baseband processing portion 230. The CPU 10 receiving this signal reads the update program from the flash memory 21 and writes the same in the prescribed address space of the SRAM 22 employed as the working memory of the CPU 10. At this time, an address detecting portion 14 detects that data has been written in the prescribed address space of the SRAM 22 and exercises control for writing the same data also in the FeRAM 13, thereby writing the update program also in the FeRAM 13.

When completely writing the update program in the SRAM 22, the CPU 10 executes an operation of updating the system program according to the update program. First, the CPU 10 collectively erases data in the flash memory 21 along with the update program. Then, the CPU 10 transmits a transmission request for the updated system program to the transmitter (not shown). When receiving the updated system program, the CPU 10 writes the system program demodulated by the baseband processing portion 230 in the flash memory 21. When entirely writing the system program in the flash memory 21, the CPU 10 rewrites the update program stored in the SRAM 22 in the flash memory 21, and ends the update operation.

If the portable terminal 200 loses power during this update operation, the CPU 10 detects that the power has been lost during the update operation upon subsequent power supply. The CPU 10 transmits information of this detection to the address detecting portion 14. The address detecting portion 14 receiving the information from the CPU 10 rewrites the update program stored in the FeRAM 13 in the SRAM 22. The CPU 10 executes the operation of updating the system program again according to the update program rewritten in the SRAM 22.

When updating the program, the CPU 10 stores the update program in the SRAM 22 and thereafter temporarily erases the update program from the flash memory 21 along with the system program. In this case, the FeRAM 13 also holds the update program according to the second embodiment as described above, whereby the CPU 10 can store the update program held in the FeRAM 13 in the SRAM 22 again upon subsequent power supply although the update program stored in the SRAM 22 disappears if the portable terminal 200 loses power during the operation of updating the system program. Thus, the portable terminal 200 can reliably prevent the update program from disappearance when losing power, thereby executing the operation of updating the program again.

A portable terminal, generally driven by a battery, frequently loses power during processing due to power consumption in the battery. However, the portable terminal 200 according to the second embodiment, writing the same data as that written in the SRAM 22 also in the FeRAM 13 as hereinabove described, can reliably prevent loss of data also when losing power during processing. Thus, the portable terminal 200 can continue the processing, performed before the power has been lost, when supplied with power again.

The remaining effects of the second embodiment are similar to those of the aforementioned first embodiment.

### Third Embodiment

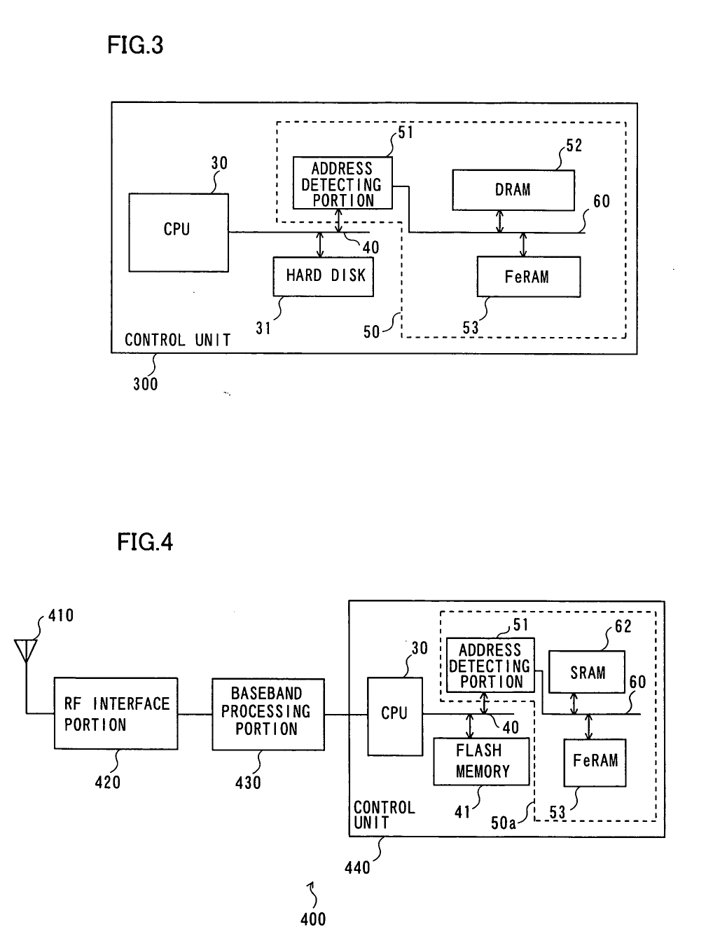

The structure of a control unit 300 according to a third embodiment of the present invention is now described with reference to FIG. 3. In the control unit 300 according to the third embodiment, an FeRAM 53 stores partial data among data used in the control unit 300 while a DRAM 52 stores remaining data, dissimilarly to the control unit 100 according to the aforementioned first embodiment.

The control unit 300 according to the third embodiment comprises a CPU 30, a hard disk 31 and a memory portion 50, as shown in FIG. 3. The memory portion 50 includes an address detecting portion 51, the DRAM 52 and the FeRAM 53. The CPU 30 is an example of the “control portion” in the present invention. The DRAM 52 is an example of the “volatile memory” in the present invention, and the FeRAM 53 is an example of the “nonvolatile memory” in the present invention.

The CPU 30, the hard disk 31 and the memory portion 50 are connected to a bus 40, for transmitting/receiving data to/from each other through the bus 60.

The CPU 30 executes overall control and operation of the control unit 300 according to a program. The CPU 30 also has a function of monitoring a power supply voltage and detecting loss of power during data processing. The hard disk 31 stores the program for driving the CPU 30 and data used for the program. This hard disk 31 may be replaced with a flash memory.

The memory portion 50, which is a virtual memory employed as a working memory temporarily holding data used in the control unit 300, is constituted of the address detecting portion 51, the DRAM 52 and the FeRAM 53 in actuality. The control unit 300 employs a prescribed one of address spaces allocated to the memory portion 50 as a working memory of the CPU 30, for writing data necessary for operation of the CPU 30 and results of the operation in the prescribed address space of the virtual memory portion 50. The prescribed address space used as the working memory of the CPU 30 may be regularly fixed, or may be rendered variable with the program.

The address detecting portion 51 monitors access to the memory portion 50, and determines the accessed address space of the memory portion 50. When detecting access to the address space employed as the working memory of the CPU 30, the address detecting portion 51 exercises control for accessing the FeRAM 53 through the bus 60. When detecting access to an address space other than that employed as the working memory of the CPU 30, on the other hand, the address detecting portion 51 exercises control for accessing the DRAM 52 through the bus 60.

In other words, the FeRAM 53 directly stores data of the address space employed as the working memory of the CPU 30 among data stored in the memory portion 50, while the DRAM 52 directly stores the remaining data. Also when the control unit 300 loses power, therefore, the FeRAM 53 holds data having been used in the CPU 30 unlost.

The DRAM 52 may simply be a volatile memory such as an SRAM, for example, in view of the operating speed and the rewritable frequency. Further, the FeRAM 53 may simply be a nonvolatile memory such as an MRAM, for example.

Control, address and data signals for the bus 40 and the memory portion 50 are connected to the address detecting portion 51, which in turn monitors presence/absence of access to the memory portion 50 with the control signal for the memory portion 50. When detecting access to the memory portion 50, the address detecting portion 51 determines whether or not the address space employed as the working memory of the CPU 30 is accessed from the value of the address signal. The CPU 30 transmits information of the address space employed as the working memory thereof to the address detecting portion 51.

When the address space of the memory portion 50 employed as the working memory of the CPU 30 is accessed, the address detecting portion 51 generates control and address signals for the FeRAM 53. When the access is writing, the address detecting portion 51 generates a write data signal and accesses the FeRAM 53 through the bus 60. When the access is reading, on the other hand, the address detecting portion 51 receives read data from the FeRAM 53 and transfers the same to the data signal of the bus 40.

When an address space of the memory portion 50 other than that employed as the working memory of the CPU 30 is accessed, the address detecting portion 51 generates control and address signals for the DRAM 52. When the access is writing, the address detecting portion 51 generates a write data signal and accesses the DRAM 52 through the bus 60. When the access is reading, on the other hand, the address detecting portion 51 receives read data from the DRAM 52 and transfers the same to the data signal of the bus 40.

Operations of the control unit 300 shown in FIG. 3 are now described. The CPU 30 properly downloads the program stored in the hard disk 31, for executing overall control and operation of the control unit 300 according to this program. At this time, the CPU 30 reads data used therein from the hard disk 31 and writes the same in the prescribed address space of the memory portion 50 employed as the working memory thereof. The CPU 30 also writes and holds results of operation thereof in the prescribed address space of the memory portion 50. The memory portion 50 further temporarily stores various additional data used in the control unit 300.

When data is written in the memory portion 50, the address detecting portion 51 detects this writing in the memory portion 50 and determines whether or not the data is written in the prescribed address space employed as the working memory of the CPU 30. When determining that the data is written in the prescribed address space, the address detecting portion 51 writes the data also in the FeRAM 52. When determining that the data is written in an address space other than the prescribed one, on the other hand, the address detecting portion 51 writes the data in the DRAM 52.

When the control unit 300 loses power during data processing, data written in the DRAM 52 is entirely lost while data written in the FeRAM 53 remains unlost. In other words, the FeRAM 53 holds data necessary for operations of the CPU 30 as such also when the control unit 300 loses power. When detecting that the power has been lost during data processing upon subsequent power supply, the CPU 30 continues processing performed before the power has been lost through the data held in the FeRAM 53.

According to the third embodiment, as hereinabove described, the control unit 300, capable of directly storing data to be held before losing power in the FeRAM 53 as hereinabove described, can avoid such a problem arising in the prior art that power is lost before the control unit 300 completely writes the data in the FeRAM 53 when writing the data from the DRAM 52 in the FeRAM 53 upon reduction of the power supply voltage. Thus, the control unit 300 can reliably prevent loss of data also when losing power during data processing. Further, the FeRAM 53 requires a capacitance for only data to be held before the control unit 300 loses power and is used as the working memory of the control unit 300 as such, whereby the capacitance of the DRAM 52 can also be reduced. Consequently, the cost for the control unit 300 and power consumption therein can be suppressed.

According to the third embodiment, as hereinabove described, the memory portion 50 includes the address detecting portion 51 exercising control for writing data in the FeRAM 53 when detecting data writing in the prescribed address space among those allocated to the memory portion 50, whereby the control unit 300 can simply detect whether or not data written in the memory portion 50 is to be held before losing power from the address storing the data.

According to the third embodiment, as hereinabove described, the FeRAM 53 stores partial data used in the CPU 30, whereby the control unit 300 can restore the data used in the CPU 30 from the FeRAM 53 upon subsequent power supply after losing power, thereby continuing data processing performed before the lower has been lost.

According to the third embodiment, as hereinabove described, the FeRAM 53 formed by a ferroelectric memory and employed as the nonvolatile memory can easily store partial data among those used in the control unit 300, whereby the control unit 300 can reliably prevent loss of data also when losing power during data processing.

### Fourth Embodiment

The structure of a portable terminal 400 according to a fourth embodiment of the present invention is now described with reference to FIG. 4. According to the fourth embodiment, a control unit 440 similar to the control unit 300 according to the third embodiment is applied to the portable terminal 400.

The portable terminal 400 according to the fourth embodiment comprises an antenna 410, an RF interface portion 420, a baseband processing portion 430 and the control unit 440, as shown in FIG. 4.

The antenna 410 receives a signal from a transmitter (not shown) through radio. The RF interface portion 420 frequency-converts the signal of a radio frequency received in the antenna 410 to a baseband signal. The baseband processing portion 430 demodulates the baseband signal.

The control unit 440 implements various applications by controlling the portable terminal 400 with the demodulated baseband signal and a built-in program (system program) in a structure similar to that of the control unit 300 according to the third embodiment. However, a flash memory 41 and an SRAM 62 substitute for the hard disk 31 and the DRAM 52 of the control unit 300 respectively. The remaining blocks of the control unit 440 are identical to those of the control unit 300 according to the third embodiment, and denoted by the same reference numerals.

The flash memory 41 of the control unit 440 stores the built-in program. The portable terminal 400 can update the built-in program, in order to solve inconveniences of the system or add functions thereto. Therefore, an update program for updating the system program is written in the flash memory 41, in addition to the ordinary built-in program (system program).

When the portable terminal 400 ordinarily operates, a CPU 30 controls the portable terminal 400 according to the system program. At this time, the control unit 440 of the portable terminal 400 backs up working data used therein in a memory portion 50a similarly to the control unit 300 according to the third embodiment.

When an address space of the memory portion 50a for preserving data used in the CPU 30, i.e., an address space used as a working memory of the CPU 30 is accessed, an address detecting portion 51 exercises control for accessing the FeRAM 53. When an access of the memory portion 50a other than that used as the working memory of the CPU 30 is accessed, on the other hand, the address detecting portion 51 exercises control for accessing the SRAM 62.

In other words, the FeRAM 53 directly stores data of the address space employed as the working memory of the CPU 30 among data stored in the memory portion 50a, while the DRAM 62 directly stores the remaining data. Also when the portable terminal 400 loses power, therefore, the FeRAM 53 holds data having been used in the CPU 30 unlost.

In order to update the system program, the CPU 30 rewrites data of the system program according to the update program. The procedure for updating the system program is now described.

The transmitter (not shown) transmits a signal indicating presence of an updated system program, so that the portable terminal 400 receives this signal through the antenna 410 and transmits the same to the CPU 30 of the control unit 440 through the RF interface portion 420 and the baseband processing portion 430.

The CPU 30 receiving this signal reads the update program from the flash memory 41 and writes the same in the prescribed address space of the memory portion 50a employed as the working memory of the CPU 30. At this time, the address detecting portion 51 of the memory portion 50a detects that data is written in the prescribed address space of the memory portion 50a employed as the working memory of the CPU 30 and writes the actual update program in the FeRAM 53 of the memory potion 50a.

When completely writing the update program in the FeRAM 53 of the memory portion 50a, the CPU 30 reads the update program stored in the FeRAM 53 and executes an operation of updating the system program according to the read update program. First, the CPU 30 collectively erases data in the flash memory 41 along with the update program. Then, the CPU 30 transmits a transmission request for the updated system program to the transmitter (not shown). When receiving the updated system program, the CPU 30 writes the system program demodulated by the baseband processing portion 430 in the flash memory 41. When entirely writing the system program in the flash memory 41, the CPU 30 rewrites the update program stored in the FeRAM 53 in the flash memory 41, and ends the update operation.

If the portable terminal 400 loses power during this update operation, the FeRAM 53 holds the update program unlost. When detecting that the power has been lost during the update operation upon subsequent power supply, the CPU 30 executes the operation of updating the system program again according to the update program stored in the FeRAM 53.

When updating the program, the CPU 30 temporarily erases the update program from the flash memory 41 along with the system program. In this case, the FeRAM 53 also holds the update program according to the fourth embodiment as described above, whereby the CPU 30 can reliably prevent loss of the update program when the portable terminal 400 loses power, thereby executing the operation of updating the program again. Further, the CPU 30 updates the program by reading the update program held in the FeRAM 53 without storing the update program in the SRAM 62, whereby the capacitance of the SRAM 62 can also be reduced. Consequently, the cost for the control unit 440 and power consumption therein can be suppressed.

A portable terminal, generally driven by a battery, frequently loses power during processing due to power consumption in the battery. However, the portable terminal 400 according to the fourth embodiment, storing partial data in the FeRAM 53 among those used in the control unit 440 as hereinabove described, can reliably prevent loss of data also when losing power during processing. Thus, the portable terminal 400 can continue the processing, performed before the power has been lost, when supplied with power again.

The remaining effects of the fourth embodiment are similar to those of the aforementioned third embodiment.

Although the present invention has been described and illustrated in detail, it is clearly understood that the same is by way of illustration and example only and is not to be taken by way of limitation, the spirit and scope of the present invention being limited only by the terms of the appended claims.

For example, while the CPU detects that power has been lost in each of the aforementioned first and second embodiments, the present invention is not restricted to this but a power loss detecting portion may alternatively be separately provided. In this case, the address detecting portion may receive information on loss of power from the power loss detecting portion.

While the CPU detects that power has been lost in each of the aforementioned third and fourth embodiments, the present invention is not restricted to this but a power loss detecting portion may alternatively be separately provided. In this case, the CPU may receive information on loss of power from the power loss detecting portion.

While the control unit of the portable terminal rewrites the data stored in the FeRAM in the DRAM upon subsequent power supply when detecting that power has been lost during data processing in each of the aforementioned first and second embodiments, the present invention is not restricted to this but the control unit or the portable terminal may alternatively regularly rewrite data stored in the FeRAM in the DRAM upon power supply. In this case, loss of power may not be detected during data processing while the control unit or the portable terminal rewrites data from the FeRAM in the DRAM also upon power supply after a normal power-down operation, whereby the control unit according to the present invention can be implemented in a simple structure.

While the FeRAM also stores the corresponding address of the DRAM along with the data in each of the aforementioned first and second embodiments, the present invention is not restricted to this but an additional nonvolatile memory may alternatively store only the base address of the prescribed address space of the DRAM used as the working memory of the CPU so that the FeRAM preserves only data. In this case, the address relation between the DRAM and the FeRAM may be obtained through operation based on the base address. While an operation circuit for address calculation is necessary in this case, the capacitance of the nonvolatile memory can be reduced since the FeRAM may preserve only data.

While the aforementioned second and fourth embodiments are applied to the portable terminals, the present invention is not restricted to this but is also applicable to a system such as a digital television or a personal computer updating a system program. While the portable terminal updates the system program through a radio line in each of the second and fourth embodiments, the system program may alternatively be updated through a cable line. Further alternatively, the system program may be updated by inserting a recording medium such as an optical disk or a memory card storing the updated program into the system.

What is claimed is:

1. A control unit comprising:
a control portion partially or entirely controlling said control unit;
a volatile memory temporarily storing data used in said control unit; and
a nonvolatile memory holding data of said volatile memory,
for writing the same data as that written in said volatile memory also in said nonvolatile memory upon occurrence of writing in said volatile memory.

2. The control unit according to claim 1, further comprising an address detecting portion detecting whether or not data is written in a prescribed address space of said volatile memory,
for writing the same data as that written in said volatile memory also in said nonvolatile memory when said address detecting portion detects that data is written in said prescribed address space of said volatile memory.

3. The control unit according to claim 2, wherein
said address detecting portion detects whether or not data is written in an address space for temporarily storing data used in said control portion.

4. The control unit according to claim 1, wherein
a speed for writing data in said nonvolatile memory is equivalent to or in excess of a speed for writing data in said volatile memory.

5. The control unit according to claim 4, wherein
said nonvolatile memory includes either a ferroelectric memory or a magnetoresistive memory.

6. The control unit according to claim 1, rewriting data held in said nonvolatile memory in said volatile memory when power starts to be supplied to said control unit.

7. A portable terminal comprising:
an antenna receiving a radio signal;
a conversion portion frequency-converting received said radio signal to a baseband signal;
a processing portion demodulating said baseband signal;
a control portion partially or entirely controlling said portable terminal on the basis of demodulated said baseband signal;
a volatile memory temporarily storing data used in said portable terminal; and
a nonvolatile memory holding data of said volatile memory,
for writing the same data as that written in said volatile memory also in said nonvolatile memory upon occurrence of writing in said volatile memory.

8. The portable terminal according to claim 7, further comprising an address detecting portion detecting whether or not data is written in a prescribed address space of said volatile memory,
for writing the same data as that written in said volatile memory also in said nonvolatile memory when said address detecting portion detects that data is written in said prescribed address space of said volatile memory.

9. The portable terminal according to claim 8, wherein
said address detecting portion detects whether or not data is written in an address space for temporarily storing data used in said control portion.

10. The portable terminal according to claim 7, wherein
a speed for writing data in said nonvolatile memory is equivalent to or in excess of a speed for writing data in said volatile memory.

11. The portable terminal according to claim 10, wherein
said nonvolatile memory includes either a ferroelectric memory or a magnetoresistive memory.

12. The portable terminal according to claim 7, rewriting data held in said nonvolatile memory in said volatile memory when power starts to be supplied to said portable terminal.

13. A control unit comprising:
a control portion partially or entirely controlling said control unit; and
a memory portion including a volatile memory and a nonvolatile memory temporarily storing data used in said control unit, wherein
said memory portion stores partial data used in said control unit in said nonvolatile memory while storing remaining data in said volatile memory.

14. The control unit according to claim 13, wherein
said memory portion further includes an address detecting portion exercising control for writing data in said nonvolatile memory when detecting data writing in a prescribed address space among address spaces allocated to said memory portion.

15. The control unit according to claim 13, wherein
said partial data stored in said nonvolatile memory is data used in said control portion.

16. The control unit according to claim 13, wherein
said nonvolatile memory includes either a ferroelectric memory or a magnetoresistive memory.

17. A portable terminal comprising:
an antenna receiving a radio signal;
a conversion portion frequency-converting received said radio signal to a baseband signal;
a processing portion demodulating said baseband signal;
a control portion partially or entirely controlling said portable terminal on the basis of demodulated said baseband signal; and
a memory portion including a volatile memory and a nonvolatile memory temporarily storing data used in said portable terminal, wherein
said memory portion stores partial data used in said portable terminal in said nonvolatile memory while storing remaining data in said volatile memory.

18. The portable terminal according to claim 17, wherein
said memory portion further includes an address detecting portion exercising control for writing data in said nonvolatile memory when detecting data writing in a prescribed address space among address spaces allocated to said memory portion.

19. The portable terminal according to claim 17, wherein
said partial data stored in said nonvolatile memory is data used in said control portion.

20. The portable terminal according to claim 17, wherein
said nonvolatile memory includes either a ferroelectric memory or a magnetoresistive memory.
